(19) United States
(12) Patent Application Publication
(10) Pub. No.: US 2012/0188696 A1
(43) Pub. Date: Jul. 26, 2012

(54) MARINE HOUSING FOR A SUBMERSIBLE INSTRUMENT

(75) Inventors: Roger Gildseth, Nesoya (NO); Dag Skyrud, Heggedal (NO)

(73) Assignee: ISURVEY, Billingstad (NO)

(21) Appl. No.: 13/393,435

(22) PCT Filed: Aug. 30, 2010
(86) PCT No.: PCT/NO2010/000321

§ 371 Date: Apr. 16, 2012

Related U.S. Application Data
(60) Provisional application No. 61/255,561, filed on Oct. 28, 2009.

(30) Foreign Application Priority Data
Aug. 30, 2009 (NO) 20092906

(51) Int. Cl. H05K 5/02

(52) U.S. Cl. 361/679.01

(57) ABSTRACT

A method for housing a marine submersible instrument includes providing two or more shell portions for forming a complete shell with a cavity, assembling said shell portions around said instrument thereby forming an enveloping shell, and arranging one or more ropes to bind said two or more said shell portions together in their assembled positions about said instrument.

### FIELD OF THE INVENTION

The present invention relates to a marine instrument protective housing resistant to mechanical forces such as punching, bending and scraping.

### BACKGROUND

Underwater structural devices such as large mooring anchors or templates must be lowered and installed to predetermined positions. In order to improve safety, predictability, and speed of operations, the offshore oil and gas industry has grown ever more demanding on the supply of accurate location for underwater equipment. In order to provide such data, during installation, permanent monitoring, or before removal, it has been common to link an acoustic transponder to the submerged equipment, and to locate it thanks to a corresponding transducer on board a related vessel.

However, such transponder, typically a cylinder of a few centimetres diameter and a few decimetres lengths, may be subject to very rough handling. This is in particular the case for transponders designed to locate anchors mooring drilling vessels or platforms. The mooring line usually comprises very heavy chains or very large diameter ropes of polypropylene or similar high strength rope. Subject to a mechanically rough descent while following a mooring chain or an anchor from the ship's deck to the sea bottom, rough treatment when the anchor, possibly with the transponder instrument, penetrates the sediments, and to the same extreme handling during recovery, transponders in the field have shown low robustness and reliability, resulting in loss of positioning accuracy of the anchors, higher costs and reduced safety.

### BACKGROUND ART

The common practice for attaching transponder beacons for anchors and the like has been to use protection and floatation collars. Two half-floating shells are clamped around the body of the beacon. These buoys do leave both ends free and unprotected from bad treatment. The bowline may be attached directly to an end portion with an attachment eye on the instrument housing. The connection may be made using a chain portion, which induces a risk of breaking the attachment eye or the end of the instrument while handling the instrument in a deck crane. The unprotected end portion of the instrument housing is also subject to hitting the deck, chain links, delta plates or any mechanical component during its handling while connected to the anchor or anchor line. Prior art has the significant disadvantage that the bowline, often a chain or a carabine hook or other metal shackle which is connected directly to one end, usually the lower portion of the instrument, which damages the end of the instrument during deck handling or lowering. The buoyant housing of some of the prior art does not form part of the connection to the bowline.

WO2010/062184 describes a protection housing rigidly attached to the shank of an anchor, the protection housing holding a sensor and transmitter device. Such a protection housing rigidly attached to the anchor will require modifications to the anchor and will further be subject to strong mechanical forces when the anchor is dragged through the sediments and there is a risk of damage to the sensor and transmitter. Furthermore, the sensor and transmitter will necessarily end up at the same depth as the anchor, which may be rather deep in the sediments, and may thus not be able to communicate with surface vessels.

Brief summary of the invention

In a material aspect of the invention, it is a marine housing for a submersible instrument (2), comprising:

two or more shell portions (3a, 3b, 3c) for mechanically protecting said instrument (2), wherein the novel features are:
said shell portions (3a, 3b, 3c) arranged for being assembled as an enveloping shell (1) forming a cavity (11) for mechanically protecting said instrument (2),
two or more of said shell portions (3a, 3b, 3c) comprising one or more ropes (5) for binding said shell portions (3a, 3b, 3c) together in their assembled positions forming said shell (1).

In a preferred embodiment of the invention two or more of said shell portions (3a, 3b, 3c) are provided with channels (4) for threading or guiding said one or more ropes (5). This stabilizes the shell during assembly and also during use both while in the sea and particularly protects the rope against wear.

In a preferred advantageous embodiment of the invention the one or more ropes (5) are arranged for reinforcing said shell (1) under tension of said one or more ropes (5) by providing compressive forces to said shell portions (3a, 3b, 3c).

In another aspect of the invention, it is a method for housing a marine submersible instrument (2), comprising: providing two or more shell portions (3a, 3b, 3c) for forming a complete shell (1) with a cavity (11), assembling said shell portions (3a, 3b, 3c) around said instrument (2) thereby forming an enveloping shell (1), and arranging one or more ropes (5) to bind said two or more said shell portions (3a, 3b, 3c) together in their assembled positions about said instrument (2).

According to a preferred embodiment of the invention the method of the invention comprises threading or guiding the one or more ropes (5) through channels (4) in two or more of the shell portions (3a, 3b, 3c). Further preferred embodiments are described in the dependent claims.

Connecting a bowline from the shell holding the instrument, generally directly to a part of an anchor line such as a shackle or chain link or triple plate may provide a significant advantage as the housing of the invention allows the instrument to mechanically tolerate being dragged through sediments, thus the anchor may be more precisely positioned. This is an advantage over the prior art instruments which may not withstand being dragged through sediments. It may also be advantageous to connect the shell (1) directly but releasably to the anchor line already on deck of the vessel in order to remain in a controllable position to avoid beatings from chain being dragged along the deck, and subsequently to be extended in the entire length of the bowline when the anchor has landed.

### BRIEF DESCRIPTION OF THE FIGURES

The background art has been illustrated together with the invention in the following drawing figures. The drawings are meant to illustrate the invention.

FIG. 1 is an illustration of an anchor handling vessel connected to an anchor line and to an anchor at the seafloor. The anchor line is provided with a sonar buoy according to the invention, the sonar buoy for locating the anchor. In this illustration the buoy is attached close to a delta plate, on the so-called recovery side of the anchor. Also illustrated in more detail is an isometric view of the assembled sonar buoy housing of the invention

FIG. 2: illustrates alternative positions for the sonar buoy in the vicinity of the anchor. Other positions are possible. The precise position for attachment for the sonar buoy and lengths of ropes will be selected in order to prevent the buoy from being clamped and damaged by the anchor.

FIG. 3 illustrates a background art sonar buoy of the two-shell lateral clamp type which only covers part of the cylindrical side face of the central portion of the instrument, and exposes both ends of the instrument housing. The two shells are provided with handles.

FIG. 4 in its lower portion is a section of an embodiment of the invention with a rope from a bow line to the left, through a channel through a nose portion shell and through three central body shell sections and through an end (top) shell section, and back through an opposite side. The rope is arranged crossing the end shell section and returning through the shell sections back to the bow line. Also shown is an end view of a central body shell section, a cross section, an opposite end view, and a perspective view of the same.

FIG. 5 is a simplified perspective view of an embodiment of the invention. The nose portion (3a) may be made in a hard, tough material which may withstand being dragged through sediments.

FIG. 6 is a schematic part-exploded view of an embodiment of buoy according to the invention. The rope may be threaded through the nose shell portion, the central body shell sections (of which only one section is shown) and the top shell section as illustrated by the dotted line.

FIG. 7 is a top view of an embodiment of a top plate shell section according to the invention. The rope may be passed through the top plate and the remainder shell sections in channels having different depths in different embodiments.

FIG. 8 is an end view of the top plate shell portion according to two embodiments of the invention; with or without an instrument sensor/transmitter aperture (6).

FIG. 9 is a side view, section view and end view of a front shell section (3a) shaped as a nose cone having pyramidal shape according to a preferred embodiment of the invention. As the buoy generally will float with such a nose cone down, it is also called a bottom plate or bottom cone (3a). Two embodiments are illustrated: in the upper part with internal channels for the rope, and in the lower part with partly external channels.

FIG. 10 illustrates some aspects related to the mechanical load patterns which affect particularly the nose portion when subject to strong traction forces via the bowline. The angular deviations of the rope under tension through the nose cone may tend to expand and rupture the front portion of the nose cone if the mechanichal strength of the nose cone is insufficient.

FIG. 11 is a picture of an embodiment of the invention showing three hose-threaded lobes of a bottom rope configuration (shown spread for the sake of illustration) for assembled connection to a bowline.

FIG. 12 is an illustration of a bowline for connecting the rope of the buoy of the invention to an anchor or other marine structure. A loop is arranged for quick threading of the buoy around a chain, a shackle of a triple plate, or other mechanical structure near the anchor.

FIG. 13 are illustrations of a part diagonal longitudinal section and part perspective view to the left side of the sheet, and longitudinal section at the right side of the sheet, both of an embodiment of the modular housing according to the invention.

FIG. 14 is a side view of an embodiment with an instrument aperture (6′) arranged laterally.

### DETAILED DESCRIPTION OF EMBODIMENTS OF THE INVENTION

The invention will be described in detail with reference to the attached series of drawing Figures and accompanying descriptive text referring to transponder-based underwater location for anchors. The purpose of the invention is however broader, including all type of instruments, and various environments.

In its broadest definition, the invention is a marine housing for a submersible instrument (2), comprising two or more shell portions (3a, 3b, 3c) for housing and mechanically protecting the instrument (2). Particular features of the invention are represented by the facts that the shell portions (3a, 3b, 3c) are arranged for being assembled as a generally completely enveloping shell (1) forming a cavity (11) for mechanically protecting the instrument (2), and that two or more of the shell portions (3a, 3b, 3c) are provided with a rope (5) or two, or any number of ropes (5) arranged for binding the shell portions (3a, 3b, 3c) together in their assembled positions forming the shell (1).

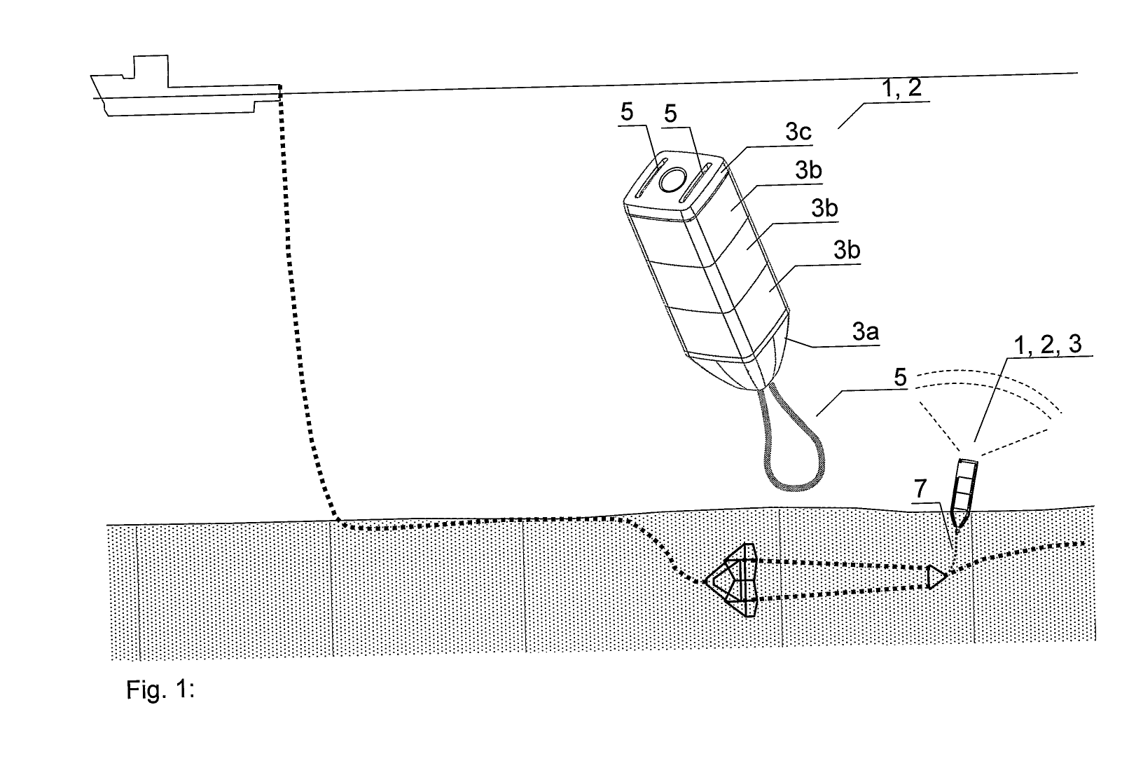

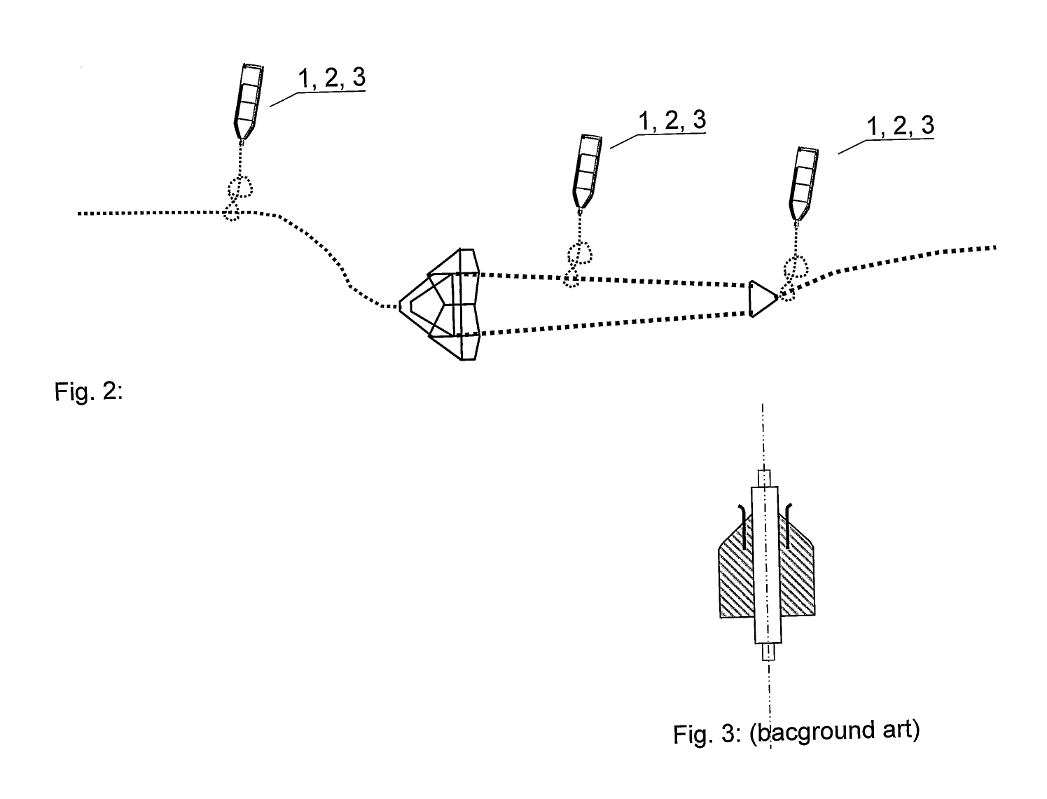

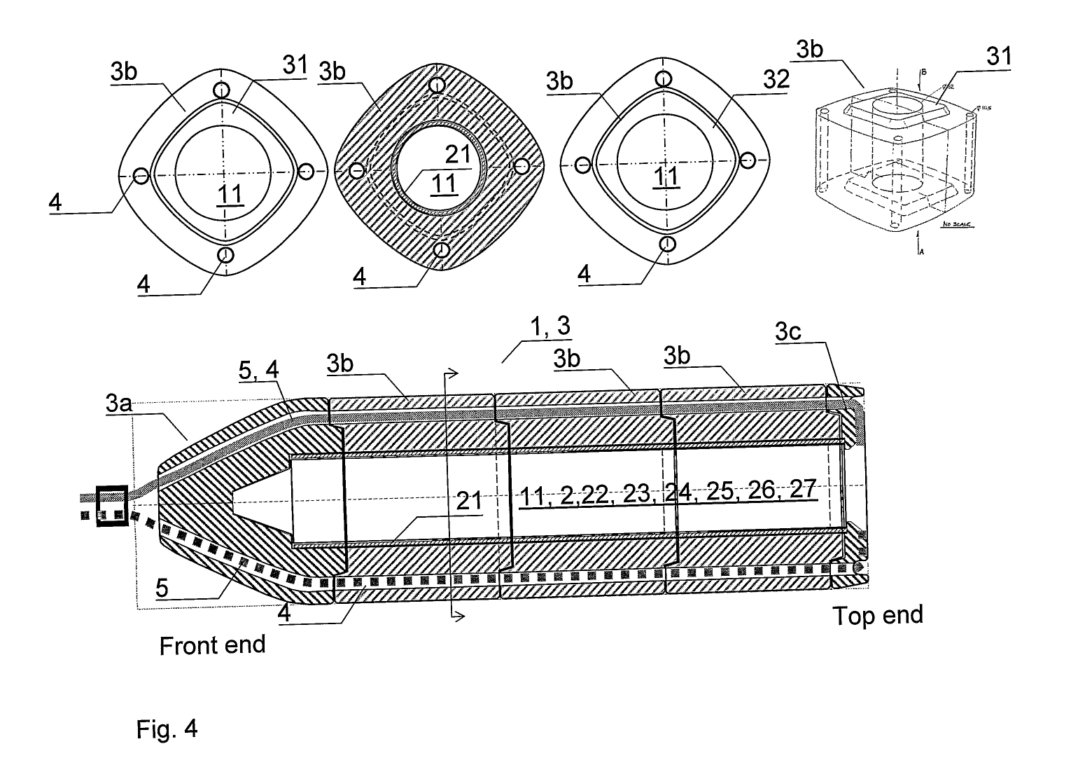

According to a preferred embodiment, the invention concerns the protective housing for a transponder or other instrument designed to locate the anchor for a vessel or a rig, during installation, removal, or at anchored location, please see FIGS. 1, 2. The housing is made up of a so-called bow, “bottom”, or front portion and a trailing or “top” portion forming two end plates. “Bottom” and “top” relates to the ordinary usage position in the sea. Those portions frame one or several body segments made of a durable material, all parts bound secured together thanks to a rope passing through each element, please see FIGS. 4, 5, and 6. The rope is attached through a bowline, preferably integral, to a subsea structure allowing the housing buoy to stand vertically up in the sea when free, with the bow section pointing down, such as illustrated in FIGS. 1 and 12. Preferably, the end of the bowline portion (7) forms an eye loop (71) sufficiently big for passing around the shell (1), please see FIG. 12. In this embodiment, the instrument buoy according to the invention may be quickly connected to the anchor line, a triple plate, or any solid structure in the vicinity of the anchor, and still be free to move relative to the anchor without being damaged by the anchor, chain links or the triple plate.

A shell comprising only one shell portion may be envisaged by the person skilled in the art, but does not have all the advantages of the invention due to the lack of modularity. The multiple-shell portions (3a, 3b, 3c) of the invention will allow several instrument module volumes or lengths of the cavity (11) formed by the shell (1) and may be adapted to several lengths of the instrument and its accompanying batteries, etc. The shell portions (3a, 3b, 3c) are in a preferred embodiment of the invention rigid and durable against wear, at least the front shell portion (3a), but one or more may be made in a softer, though wear-resistant.

According to a preferred embodiment of the invention, the marine housing of claim 1, the shell portions (3a, 3b, 3c) are provided with channels (4) for threading and/or guiding one or more of the ropes (5). The channels (4) may have several different embodiments depending on the actual implementation of the instrument buoy, such as the need for the shell to protect the ropes from wear or vice versa.

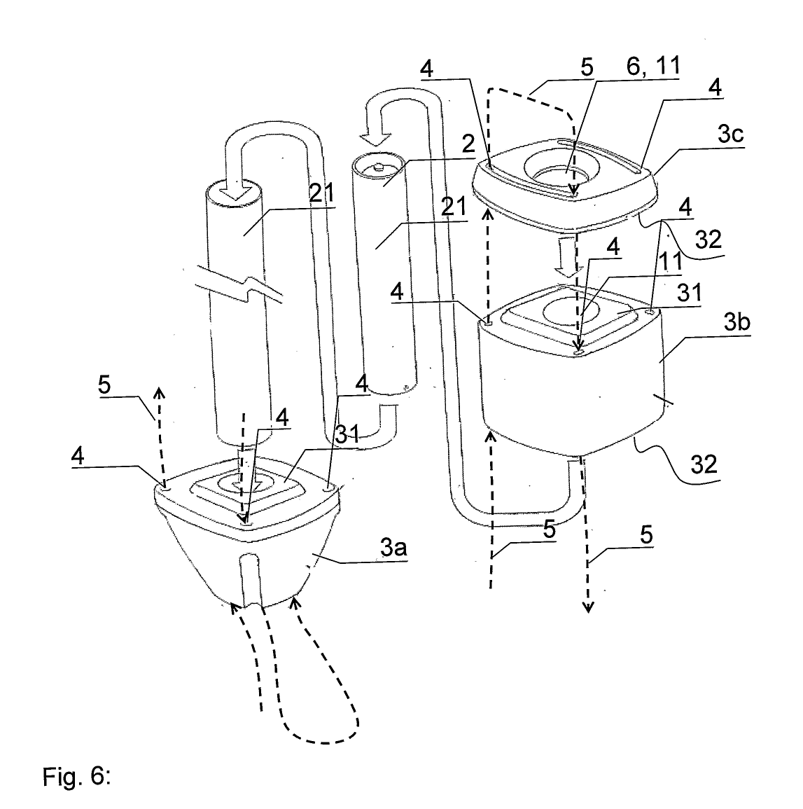

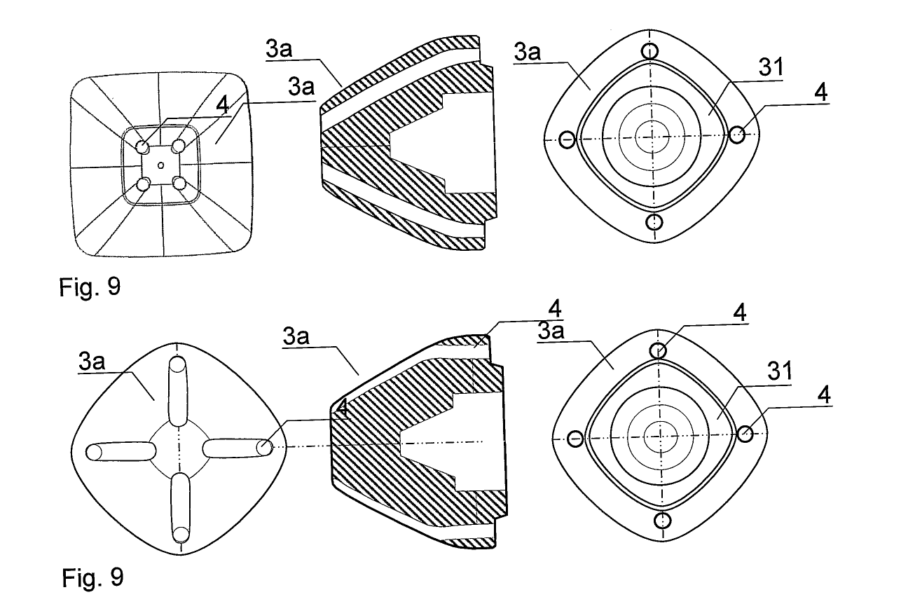

In the marine housing of the invention, one or more of said shell portions (3b) may have an internal pipe-shape forming and surrounding part of said central cavity (11). One or more of the channels (5) may extend through a significant part of one or more of the shell portions (3a, 3b, 3c). Alternatively, but with more exposed ropes, the channels (5) may be formed as eye-shaped protrusions on the outward facing surface of one or more of the shell portions (3a, 3b, 3c). The channels (5) may partly be open channels or furrows along the outward facing surface of one or more of the shell portions (3a, 3b, 3c), such as illustrated in FIG. 9, lower part of the sheet. In the rear port relative to the bowline the channels may be open, such as shown in FIG. 6, item 3c, as the top lid (3c) will be the trailing portion if the instrument is dragged through sediments.

One significant advantage of the invention in one preferred embodiment is the fact that one or more of the ropes (5) are arranged for reinforcing the shell (1) under tension of said one or more ropes (5) by providing compressive forces to the shell portions (3a, 3b, 3c). As is shown in FIGS. 4 and 6, the rope runs longitudinally through the entire buoy from the bowline, through the nose portion, the main body portions and through the top portion where the ropes cross laterally over the entire top portion and returns along another longitudinal path through channels all the way back to and through the nose portion and in the direction of the bowline. When putting the ropes under tension such as if dragging the unit through sea-floor sediments the ropes will compress the shell thus reinforce the interlocking of the shell. The shell portions according to a preferred embodiment of the invention are provided with protrusions (31) interlocking with recesses (32) in the opposite part, please see FIG. 4, a feature which will reinforce and stabilise the shell. The compression of the shell will not necessarily compress the central cavity (11) due to the rigidity of the shell parts but only keep them better interlocked.

The marine housing of the invention may be tapered slightly off behind the bow shell portion (3a) for reducing friction and wear of the remainder shell portions (3b, 3c).

The marine housing of the invention may comprise a liner pipe (21) to be arranged about said instrument (2) in the cavity (11), please see FIG. 4. The liner may be a rigid pipe or a soft tube or a spongy wrap or injected foam or gel or one or more springs. If rigid, the liner pipe may counteract lateral shear forces on the instrument.

In a preferred embodiment of the invention one or more of the shell portions (3a, 3b, 3c) have one or more sensor windows (6, 6′) for a sensor or transmitter of the instrument (2). The window (6) must be transparent for the sensor or transmitter, i.e. should be an open aperture or transparent, i.e. the aperture or window (6) having the same signal propagation properties as surrounding water or sediments. The window (6) may be an aperture, or a material piece being transparent to the signal in question, such as a cover being transparent to acoustic signals, or even having an acoustic velocity near the acoustic velocity of water. The window (6) may even be the material of the shell portion in question covering the sensor or transmitter. The buoy may contain an acoustic receiver or transmitter (22), an electromagnetic receiver or transmitter (23), a pressure sensor (24), or a sampling device (25). Alternatively, the window (6′) may be arranged laterally on the housing, such as illustrated in FIG. 14. The marine housing of the invention may comprise one or more of an energy source (26), a signal processing unit (27), and an RFID identification tag. For remote release, the marine housing of the invention may comprise a controlled release device (28), please see FIG. 1.

According to a preferred embodiment, the invention concerns the protective housing for a transponder designed to locate the anchor for a vessel or a rig, during installation, removal, or at anchored location, please see FIG. 1, 2. The housing is made of a front and end section (3a, 3c), a top and a bottom one, framing several body segments (3b) made of a hard material, secured together thanks to a rope passing through each element, please see FIGS. 4, 5, and 6.

Each subsequent body segment may have a slightly smaller diameter protruding end (31), designed to engage in the larger diameter end (32) of the neighbouring body segment, or end section, please see FIGS. 4, 6 and 9. End portions are as well designed with protrusions and recesses to allow such engagement with a neighbouring main body segment. Recesses and protrusions (32, 31) may preferably be formed in the longitudinal direction if the ropes extend in the longitudinal direction, but the shell may be subdivided also in lateral parts, and may have laterally directed recesses and protrusions also, to allow tightening in radial directions, relative to the centre of the assembled shell, and further arranged for directing lateral forces in said assembled shell (3a, 3b, 3c).

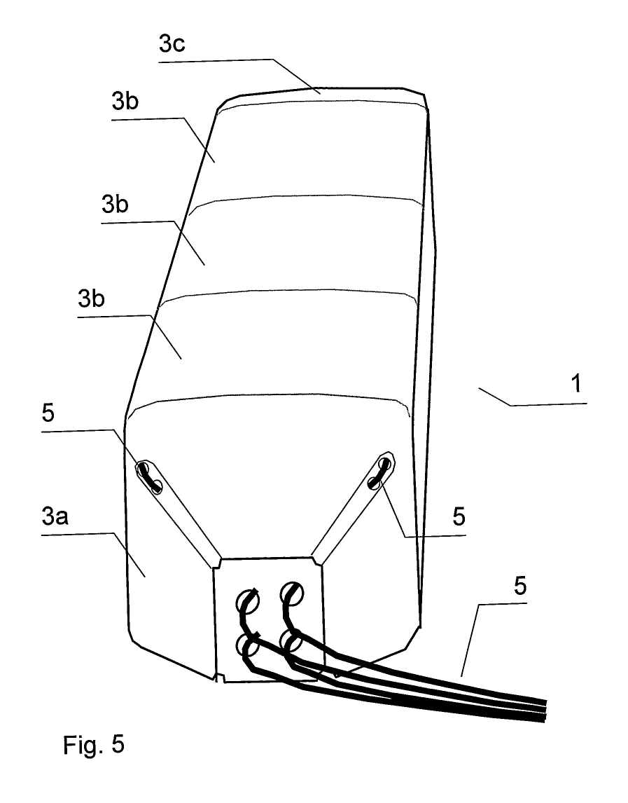

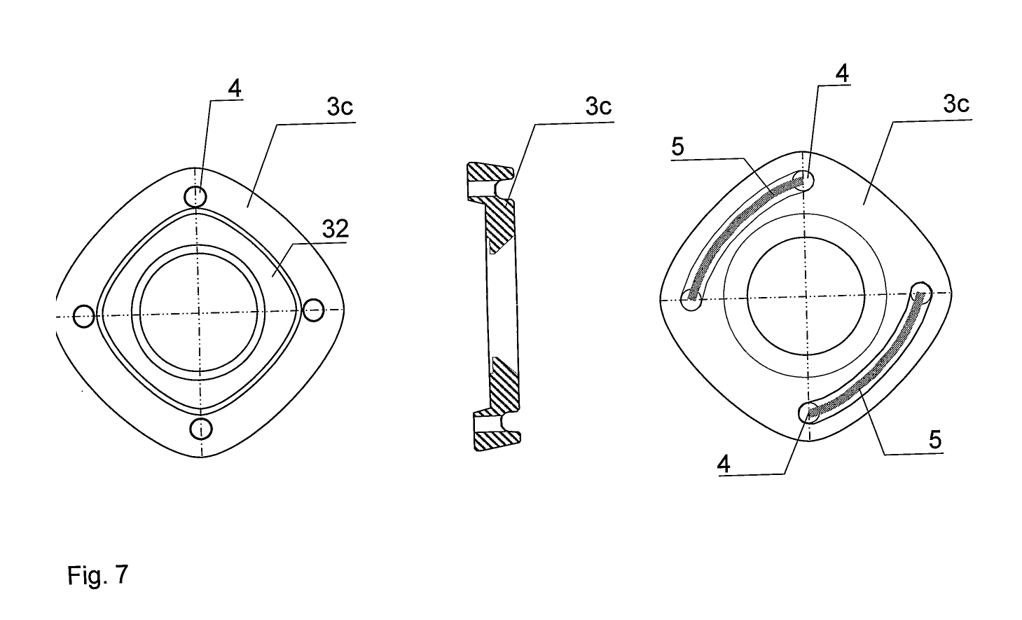

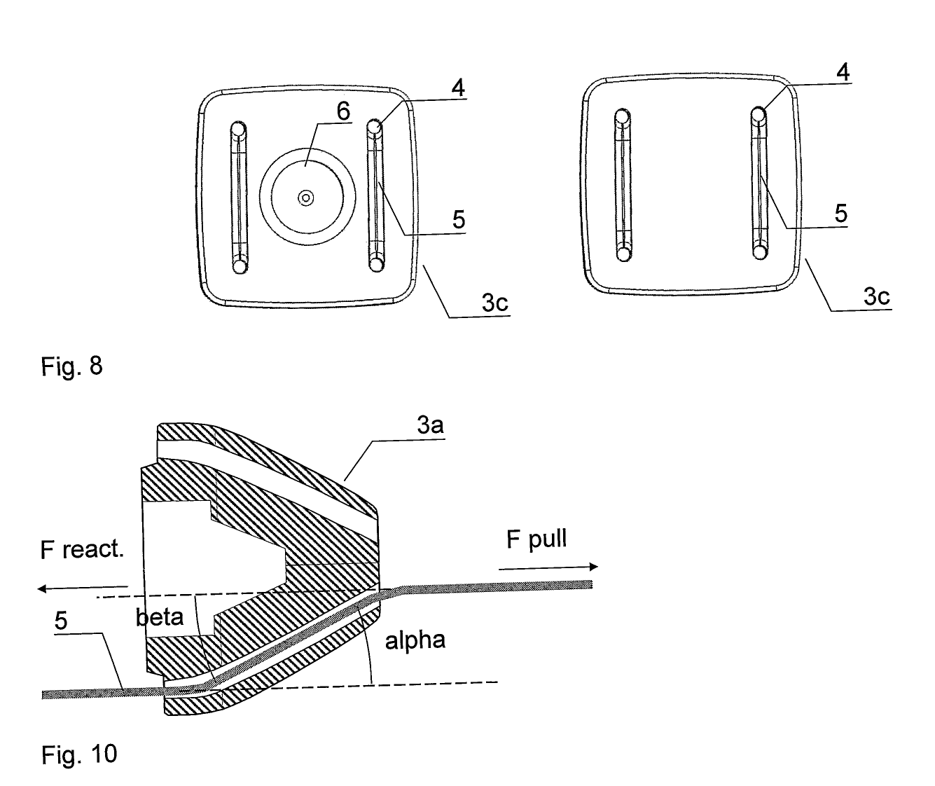

The rope (5), please see FIGS. 4 and 5, is primarily arranged in an embodiment of the present invention to hold the pieces together along the longitudinal axis. It shall prevent two neighbouring pieces from disengaging both on deck, in the water, and if dragged through the sediments at the seafloor. The rope is arranged to withstand tractions, occurring for example when the anchor penetrates the sea floor and thus possibly pulls the instrument down into the sediments, or similarly during recovery. When the rope (5) is arranged as in FIGS. 6 and 8 and kept taut it will also prevent the shell portions from moving in the lateral direction both due to the tension of the rope but also due to the mutually engaging protrusions and recesses (32, 31) of adjacent shell portions.

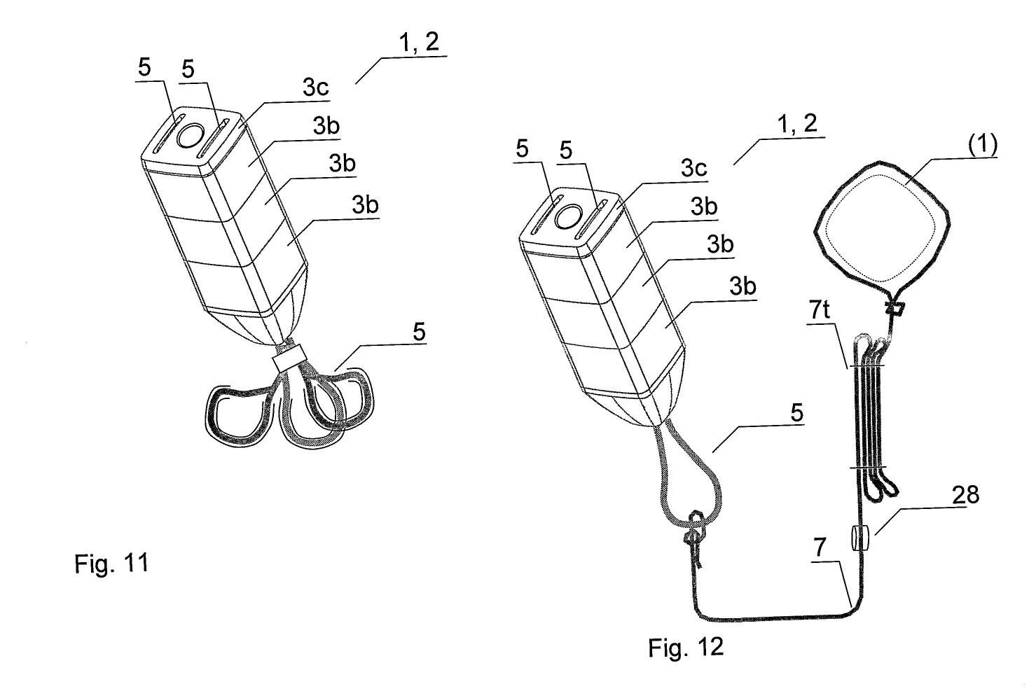

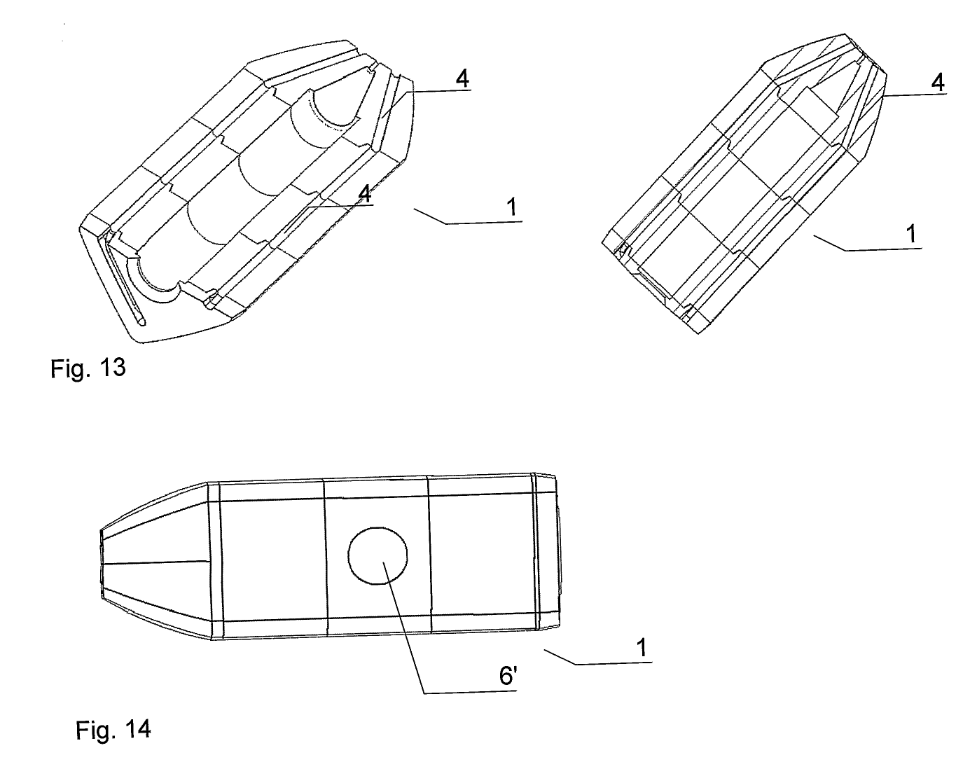

In an embodiment of the invention the rope is passed through four holes for each of the body pieces and end plate and nose portions(FIG. 4 to 10). At the bottom end, the nose portion, loops comprising the two ends and a loop of the rope, please see FIG. 11, are preferably connected by a bowline secured by a wire clamp. At the tip of the nose portion, emerging rope threads (2) in a preferred embodiment) may be wrapped together by a tie-wrap (FIG. 5). Part of the length of the bowline may be formed to a bundle by breakable strips before the bowline is attached to the anchor chain or other structure in order to keep the instrument housing near the anchor during launching, and to be extended when the bowline is loaded.

All housing pieces are preferably made of hard polymer material, designed to protect the transponder from mechanical forces, such as shocks and scraping in particular. As an acoustic transponder preferably is be held generally nearly vertical, please see FIG. 1, the housing pieces are made of a buoyant material. In a preferred embodiment, syntactic foam is used, with a depth rating of typically 1100 m, but the rating can go up to several thousand meters. Buoyancy is critical in the case of anchors that may penetrate the sea sediments quite deeply, as we want to keep the transponder over the seafloor sediments.

Several advantages are provided by having a design with several housing segments such as shown in FIG. 4. By adding or removing a body segment, the crew on deck will easily prepare for a longer or shorter beacon. A longer beacon unit will for example result from the connection of an additional battery, a data recorder, or of another instrument. Replacement of damaged or worn shell pieces is also very simple and cheaper than replacement of the full buoy shell. A segmented buoy may also show a stronger resistance or tolerance to bending or side shocks, as part of the energy may be absorbed at the connections.

End sections and particularly the bow section and also the top plate should be hard, in order to resist shocks and scraping. They need also to be in a material easy to machine or shape to required characteristics.

The top plate, please see FIGS. 6, 7, 8)is preferably provided with holes and grooves for the rope channels on the periphery. An aperture (6) may be arranged for allowing acoustic transmission by the beacon in the centre. The top plate needs to resist compression and punching forces transferred by the ropes. Its rigid structure helps distribute compression forces forward to the adjacent body pieces. The top plate should for buoyant uses be of light density, as this provides vertical stability and improves required buoyancy. In the case of a beacon, the top plate is as thin as possible in order not to unnecessarily narrow the acoustic signal cone.

The front, nose or “bottom” section, please see FIGS. 4, 5, 6, 9, and 10 shall be designed to withstand and resist strong mechanical forces such as scraping occurring when the shell is being pulled through the sediments. It shall also distribute compression forces to the neighbouring body pieces. The bottom section is designed to resist strong local tractions, due to the slight angles •and• shown by the rope, and which result in forces tending to expand the nose portion bottom plate.

As shown generally in all Figs., the marine housing of the invention is provided with the bow shell portion (3a) arranged closest to said bowline portion (7) having a pyramidal or conical shape with an apex portion (31a) directed towards said bowline portion (7), please see FIG. 12 and FIG. 1.

In a preferred embodiment, top and bottom sections are made of nylon. One advantage of this design is that an increasing traction on the rope will improve the rigidity and strength of the assembly, by setting all pieces under compression. This does of course only apply until the rope breaks. Thus parallel independent ropes (or wires) may be used in order to have redundancy if one rope breaks.

In order to position the beacon in the buoy, spacers may be added. They may compensate for a beacon shorter than the available room: one may use an additional plastic pipe in the continuity of the beacon, please see FIG. 6. A spacer may also compensate for a beacon with smaller diameter than the available room: pipe or taping may be added.

A preferred installation is quite simple. Beacon, shell sections and, if required, spacers are assembled, then secured using rope and wire clamps, please see FIG. 11. The rope connecting the buoy to the anchor, its chain, or its delta plate should comprise a bowline with an eye big enough to pass the buoy through, please see FIG. 12. The opposite end of the bowline is secured to the buoy assembly. Wire clamps are to be used on all bowlines. The excess rope is bound using tie-wraps (7t) which may break when put under strain. This is done in order to reduce the risk to have the housing trapped or clamped by the anchor or other heavy elements during maneuvering, descent or rise of the anchor.

There are many other possible embodiments to this invention. For example, one end section and the body shell pieces may be replaced by one single piece, a container to be locked with a cover thanks to the rope. However, as mechanical properties required for the body piece(s) and distal plate(s) may not be the same, such design may require a composite structure for such container. One will also lose the practical advantages of modularity cited above. Finally, should this container be very long, it may not give the expected protection against shocks and bending, as several articulations may act as energy absorbers.

Several ropes may be used in locking a shell of the invention. However, one single rope appears to allow faster assembly and higher strength.

The problems related to the general lack of robustness of transponders has triggered the invention. However, the housing of the invention may apply to several types underwater instruments, such as sensitive equipment with much electronics and sensors designed to perform collection of data or emit or receive various signals. Such equipment is in nature quite fragile, and effective mechanical protection is required when rough handling cannot be avoided. Many underwater instruments may benefit from the invention.

Not all instruments will need to be held vertical, and buoyancy is not an absolutely required property of all embodiments of the present invention. The buoy has been tested in traction in a dry trench pulled by an excavator.

The described solution may be used for transponders that are used for precise location of equipment underwater, such as anchors. One example is USBL, or Ultra Short Base Line acoustics, commonly used in the offshore oil and gas industry. USBL may even be integrated in a data system supporting the positioning of equipment underwater. Thanks to the transponder and tight integration in the positioning system such as those supplied by the assignee of this patent, the anchor can be located in real-time and visible to rig and tug boat positioning operators during installation and removal, contributing to an accurate and safe operation.

1.-28. (canceled)

29. A marine submersible instrument protective housing comprising:
a submersible instrument, said submersible instrument comprising one or more of an acoustic receiver or transmitter, a pressure sensor, or an electromagnetic receiver or transmitter, said submersible instrument for being connected to and locating underwater equipment including a well template or a large mooring anchor;
an enveloping shell forming a cavity for housing and mechanically protecting said instrument,
wherein two or more shell portions are arranged for being assembled to form said enveloping shell, and said two or more of said shell portions comprise one or more ropes for binding said shell portions together in their assembled positions forming said shell and for connecting directly or indirectly to said underwater equipment.

30. The marine housing of claim 29, wherein said two or more of said shell portions are provided with channels for threading or guiding said one or more ropes.

31. The marine housing of claim 29, wherein said one or more ropes are arranged at least partly in a longitudinal direction in said shell portions, for reinforcing said shell under tension in the longitudinal direction of said shell of said one or more ropes, thus providing compressive forces to said shell portions.

32. The marine housing of claim 29, wherein one or more of said shell portions have one or more sensor windows for a sensor or transmitter of said instrument, said one or more sensor windows being transparent for said sensor or transmitter.

33. The marine housing of claim 29, wherein said rope is provided with a bowline portion for forming a connection between one or more bow shell portions and a subsea structural member, including an anchor, a well template, a BOP, an anchor chain, a chain delta plate, a riser pipe, a casing pipe, or a Christmas tree.

34. The marine housing of claim 29, wherein said assembled shell and submersible instrument combined provide buoyancy when submerged.

35. The marine housing of claim 34, wherein one or more of said shell portions is made of a buoyant material.

36. The marine housing of claim 29, wherein one or more of said shell portions is made of a non-buoyant material.

37. The marine housing of claim 33, wherein said bow shell portions arranged closest to said bowline portion are made of a mechanically resistant material.

38. The marine housing of claim 37, wherein said one or more bow shell portions is made of a high density polymer material.

39. The marine housing of claim 33, wherein said one or more bow shell portions arranged closest to said bowline portion has a pyramidal or conical shape with an apex portion directed towards said bowline portion.

40. The marine housing of claim 29, wherein one or more of said shell portions have a pipe-shape opening forming part of said central cavity.

41. The marine housing of claim 29, wherein one or more of said channels extend internally through a significant part of one or more of said shell portions, or said channels comprise eye-shaped protrusions on the outward facing surface of one or more of said shell portions, or said channels comprise open channels or furrows along the outward facing surface of one or more of said shell portions.

42. The marine housing of claim 29, wherein said shell portions are provided with mutually arranged interlocking protrusions and recesses for interlocking said shell portions.

43. The marine housing of claim 29, wherein said submersible instrument comprises a sampling device.

44. The marine housing of claim 29, wherein said instrument comprises one or more of an energy source, a signal processing unit, and an RFID identification tag.

45. The marine housing of claim 29, further comprising a controlled-release device.

46. The marine housing of claim 29, wherein said assembled shell is tapered off behind one or more bow shell portions.

47. The marine housing of claim 29, further comprising a liner to be arranged about said instrument in said cavity.

48. The marine housing of claim 33, wherein said bowline portion forms an eye loop sufficiently big for passing around said shell for rapid connection to a marine structure.

49. The marine housing of claim 29, wherein one or more of said shell portions is modular.

50. A method for forming a protective housing for a marine submersible instrument comprising one or more of an acoustic receiver or transmitter, a pressure sensor, or an electromagnetic receiver or transmitter, said instrument for being connected to and locating underwater equipment, including a well template or a large mooring anchor, said method comprising the steps of:
providing two or more shell portions for forming a complete shell with a cavity;
assembling said shell portions around said instrument thereby forming an enveloping shell;
arranging one or more ropes to bind said two or more said shell portions together in their assembled positions about said instrument; and
connecting said one or more ropes directly or indirectly to said underwater equipment.

51. The method of claim 50, further comprising the step of threading or guiding said one or more ropes through channels in two or more of said shell portions.

52. The method of claim 50, further comprising the step of reinforcing said shell by putting said one or more ropes under tension.

53. The method of claim 50, further comprising the step of connecting said ropes to a bowline thus forming a connection to a subsea structural member, including an anchor, a well template, a BOP, an anchor chain, a chain delta plate, a riser pipe, a casing pipe, or a Christmas tree.

54. The method of claim 53, further comprising the step of connecting said bowline portion to said one or more ropes near an apex portion of said one or more bow shell portions.

55. The method of claim 50, further comprising the step of arranging a liner about said instrument in said cavity.

56. The method of claim 50, further comprising the step of connecting said shell with said instrument to a subsea structure by passing said shell through an eye loop of said bowline portion arranged about a part of said subsea structure, such as a chain link.
